(19) United States
(12) Patent Application Publication
(10) Pub. No.: US 2022/0136107 A1
(43) Pub. Date: May 5, 2022

(54) SHOWERHEAD WITH CONFIGURABLE GAS OUTLETS

(71) Applicant: Lam Research Corporation, Fremont, CA (US)

(72) Inventors: James F. LEE, Casper, WY (US); Vignesh CHANDRASEKAR, Los Angeles, CA (US); Matthew MUDROW, Tigard, OR (US)

(21) Appl. No.: 17/424,449

(22) PCT Filed: Jan. 15, 2020
(86) PCT No.: PCT/US2020/013714

§ 371 Date: Jul. 20, 2021

Related U.S. Application Data
(60) Provisional application No. 62/799,188, filed on Jan. 31, 2019.

(51) Int. Cl. C23C 16/455; C23C 16/505; H01J 37/32

(52) U.S. Cl. CPC C23C 16/45565; C23C 16/45519; H01J 37/32082; H01J 37/3244; H01J 2237/332; C23C 16/505

(57) ABSTRACT

A deposition tool including a processing chamber, a deposition pedestal for supporting a substrate in the processing chamber and for depositing a layer of material on a first surface of the substrate and a showerhead assembly having a faceplate opposing a second surface of the substrate, the faceplate of the showerhead having a plurality of configurable gas outlets arranged to distribute a purge gas adjacent the second surface of the substrate when the layer of material is being deposited on the first surface of the substrate by the deposition pedestal.

### CROSS REFERENCE TO RELATED APPLICATION

This application claims the benefit of priority of U.S. Application No. 62/799,188, filed Jan. 31, 2019, which is incorporated herein by reference for all purposes.

### BACKGROUND

The present invention relates to a deposition tool, and more particularly, to a showerhead with configurable gas outlets for controlling the flow rate of a purge gas to prevent incidental deposition on one surface of a substrate during deposition on an opposing surface of the substrate.

Deposition tools are commonly used for depositing various thin films onto substrate surfaces, such as semiconductor wafers, flat panel displays and/or photovoltaic devices. These devices are hereafter generically referred to as a “substrate”.

In the semiconductor industry, the thin films that are commonly deposited onto substrates include, but are not limited to, polysilicon, silicon nitrides, silicon dioxide, certain metals such as tungsten, nickel, aluminum, etc. These layers, which are typically formed on the device surface of the substrate, are subsequently patterned to create an integrated circuit.

The deposition of one or more layers typically causes mechanical stresses to act on a substrate. These mechanical stresses often cause bowing, meaning the substrate is no longer flat. Bowed substrates are problematic. With a non-flat substrate, misalignment during the patterning of the layers may occur, which in turn, may result in defects and lower processing yields.

To counteract bowing, it is known to deposit one or more layer(s) of material onto the backside surface opposite the device side of the substrate. These back-side layer(s) provide tensile and/or compressive strength and rigidity to the substrate, at least within temperatures at or below approximately 400° C. With certain processing steps, however, such as annealing or high temperature depositions, the substrate is exposed to very high temperatures, typically in the range of 800° C. or higher. At these higher temperatures, the back-side layer(s) tend to “relax” and lose their tensile and/or compressive strength and rigidity. As a result, the substrate will often experience bowing at high temperatures, largely rendering the back-side layer(s) ineffective in preventing bowing.

A known solution to the bowing issue at high temperatures is to perform the backside deposition at elevated temperatures, for example, in the range of 500° C. to 600° C. With a backside deposition performed within this elevated temperature range, the mechanical properties of the backside layer largely remain intact. In other words, the degree of substrate bowing is significantly reduced, even at elevated temperatures.

One by-product of backside depositions, regardless of the temperature, is that the deposition material may wrap around and incidentally deposit on the device side of the substrate as well. This incidental deposition is problematic because it may adversely affect the integrated circuitry fabricated on the device side of the substrate.

### SUMMARY

A deposition tool including a showerhead with configurable gas outlets for controlling the flow rate of a purge gas to prevent incidental deposition on one surface of a substrate during deposition on an opposing surface of the substrate is disclosed.

The deposition tool includes a processing chamber, a deposition pedestal for supporting a substrate in the processing chamber and for depositing a film of material on a first surface of the substrate. The deposition tool also includes a showerhead assembly having a faceplate opposing a second surface of the substrate. The faceplate includes a plurality of configurable gas outlets arranged to distribute a purge gas adjacent the second surface of the substrate when the film of material is being deposited on the first surface of the substrate. Any backside deposition material that wraps around the substrate and incidentally makes its way into the space above the device side of the substrate is swept away by the flow of the purge gas. As a result, incidental film deposition on the device surface of the substrate is mitigated or altogether eliminated.

The configurable gas outlets are each arranged to receive a removable insert. The gas outlets can each be configured by using different inserts. For example, inserts having a different number of holes, different hole patterns, varying hole diameters, or even inserts with no holes, can be used. By selecting different inserts the flow of the purge gas can be controlled to meet tool specifications and operating conditions. In addition, the inserts used for a given showerhead assembly do not all have to be the same. For instance, individual inserts can have more or fewer holes, different hole patterns, holes with different diameters, etc. As a result, the localized flow of the purge gas can be individually controlled at each insert location immediately above the first surface of the substrate. Since the inserts are removable, they can be changed whenever desired, including when the deposition tool is in the field. As a result, customers and end users may configure the showerhead assembly as needed or as operating parameters change.

### BRIEF DESCRIPTION OF THE DRAWINGS

The present application, and the advantages thereof, may best be understood by reference to the following description taken in conjunction with the accompanying drawings in which:

FIG. 1 is a perspective cut-away view of a deposition tool including a showerhead with configurable gas outlets in accordance with a non-exclusive embodiment of the invention.

FIG. 2 is a cross section of the showerhead assembly with configurable gas outlets in accordance with a non-exclusive embodiment of the invention.

FIGS. 3A-3B are diagrams of a faceplate and configurable gas outputs of the showerhead assembly in accordance with a non-exclusive embodiment of the invention.

FIGS. 4A-4B are diagrams of an insert used in the configurable gas outputs of the showerhead assembly in accordance with a non-exclusive embodiment of the invention.

FIG. 5 is a cross section view of the showerhead assembly and deposition pedestal in accordance with a non-exclusive embodiment of the invention.

In the drawings, like reference numerals are sometimes used to designate like structural elements. It should also be appreciated that the depictions in the figures are diagrammatic and not necessarily to scale.

### DETAILED DESCRIPTION

The present application will now be described in detail with reference to a few non-exclusive embodiments thereof as illustrated in the accompanying drawings. In the following description, numerous specific details are set forth in order to provide a thorough understanding of the present disclosure. It will be apparent, however, to one skilled in the art, that the present discloser may be practiced without some or all of these specific details. In other instances, well known process steps and/or structures have not been described in detail in order to not unnecessarily obscure the present disclosure.

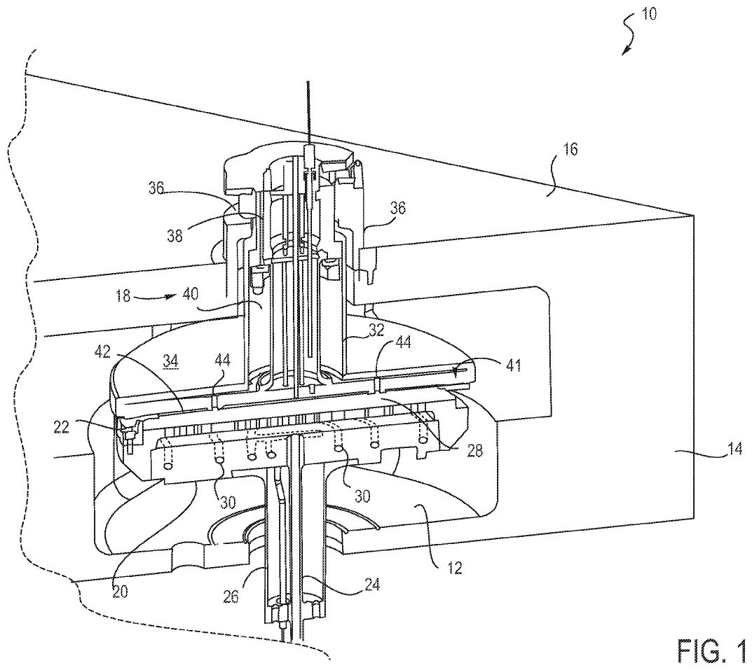

Referring to FIG. 1, a perspective cut-away view of a deposition tool 10 of a non-exclusive embodiment of the invention is shown. As described in detail below, the tool 10 is capable of (1) performing a backside substrate deposition and (2) concurrently preventing the incidental deposition of the backside deposition material on the device side of the substrate by using a purge gas. In various embodiments, the deposition tool 10 may be a Plasma Enhanced (PECVD), a Low Pressure (LPCVD), an Ultra High Vacuum (UHVCVD), an Atomic Layer Deposition (ALD), a Plasma-Enhanced Atomic Layer Deposition (PEALD) or any other type of deposition tool.

The tool 10 includes a processing chamber 12 defined by processing chamber side-walls 14 and a top plate 16. Positioned within the processing chamber 12 is a deposition pedestal 20. The deposition pedestal 20 can be any device that performs the functions of (a) supporting a substrate in the processing chamber 12 and (b) is capable of depositing a thin film on the backside of a substrate. In a non-exclusive embodiment, the deposition pedestal is a deposition reactant dispersion pedestal. The showerhead assembly 18 hangs down from the top plate 16 in a “chandelier” like fashion, while the deposition pedestal 20 provides a podium for supporting a substrate directly under the showerhead assembly 18.

The deposition pedestal 20 supports a substrate (not shown) on a substrate ring 22. The deposition pedestal 20 also supplies a deposition gas, received through a supply tube 24 provided in a stem 26 of the deposition pedestal 20, to the backside of the substrate. The deposition pedestal 20 acts to distribute the deposition gas within a gap 28 that spans across the back surface of the substrate. The deposition pedestal 20 also includes heater elements 30 that are responsible for heating the deposition reactant up to approximately 400° C. or higher during the backside deposition.

When a Radio Frequency (RF) is applied, a plasma within the processing chamber is created. As a result, a thin film is deposited on the backside of the substrate at the elevated temperature. As noted above, the purpose of this backside deposition is to prevent or reduce bowing of the substrate during subsequent processing steps including those performed at high temperatures, such as annealing.

The showerhead assembly 18 includes a cylinder 32, a top purge plate 34, and an adaptor plug 36 that is at least partially inserted into the cylinder 32. The adaptor plug 36 includes a purge gas supply inlet 38 for supplying a purge gas to a plenum 40 provided within the cylinder 32. The purge gas in the plenum 40 is then laterally distributed in via another plenum 41 under the top purge plate 34 and behind a faceplate 42, opposing the top surface of the substrate. With this arrangement, the purge gas supplied by the gas supply inlet 38, flows through the two plenums 40, 41, out a plurality of configurable gas outlets 44 on the faceplate 42, and into the area immediately above the device side of the substrate. A vacuum (not shown) draws or pulls the purge gas out of the area immediately above the device side of the substrate. As a result, the flow of the purge gas above acts to remove any deposition material that incidentally find its way in area above the device side of the substrate. As a result, any incidental device side deposition is mitigated or altogether eliminated.

In various embodiments, the purge gas or gases that are used are inert gases, such as Nitrogen, Argon, Helium, or a combination thereof.

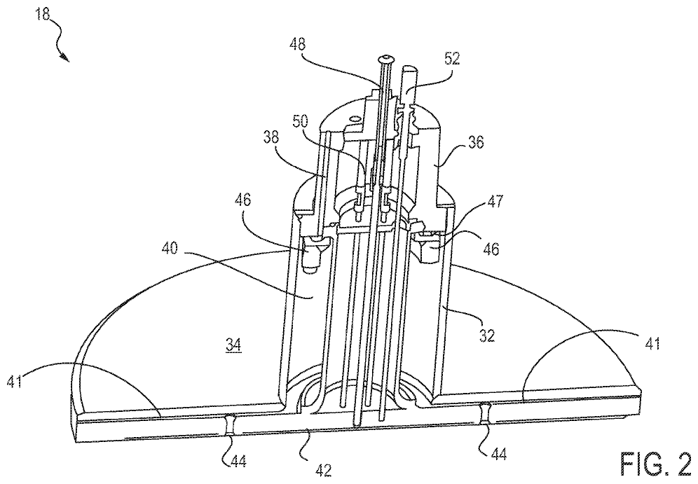

Referring to FIG. 2, a perspective, cross section view of just the showerhead assembly 18 is illustrated. As is evident in the diagram, the showerhead assembly 18 includes the cylinder 32, the top purge plate 34, the adaptor plug 36, the purge gas supply inlet 38, the plenum 40 included in the cylinder 32, the plenum 41 formed between the top purge plate 34 and the faceplate 42, and the plurality of configurable gas outlets 44.

In addition, the shower head assembly 18 includes a compression ring 46 and a clamp 47 for clamping the compression ring 46 and the adaptor plug 36 together within the cylinder 32. The adaptor plug 36 is also arranged to accommodate a number of “utilities” that are needed within the processing chamber 12. These utilities include (but are not limited to) a Radio Frequency (RF) rod 48, power supply conduit 50, and a Thermo Couple or “TC” 52.

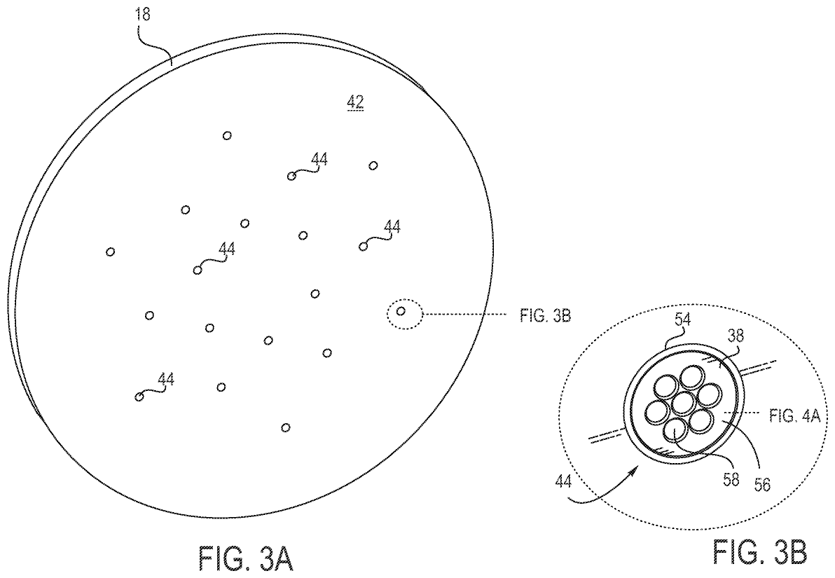

Referring to FIGS. 3A-3B, diagrams are shown of the showerhead assembly 18 including the faceplate 42 and the configurable outputs 44.

As illustrated in FIG. 3A, the faceplate 42 includes a plurality of the configurable gas outlets 44. In this particular embodiment shown, there is a total of eighteen (18) configurable gas outlets 44 arranged on the surface of the faceplate 42.

As illustrated in FIG. 3B, each of the configurable gas outlets 44 includes a hole 54 formed through the thickness of the faceplate 42. Within each hole 54, an insert 56 is inserted. In the particular embodiment shown, the insert 56 includes seven (7) smaller holes 58. As a result, this particular showerhead assembly 18 has a total of (a) eighteen (18) configurable gas outlets 44 and (b) seven (7) holes 58 per configurable gas outlet 44, or a total of one hundred and twenty six (126) holes 56 provided across the faceplate 42.

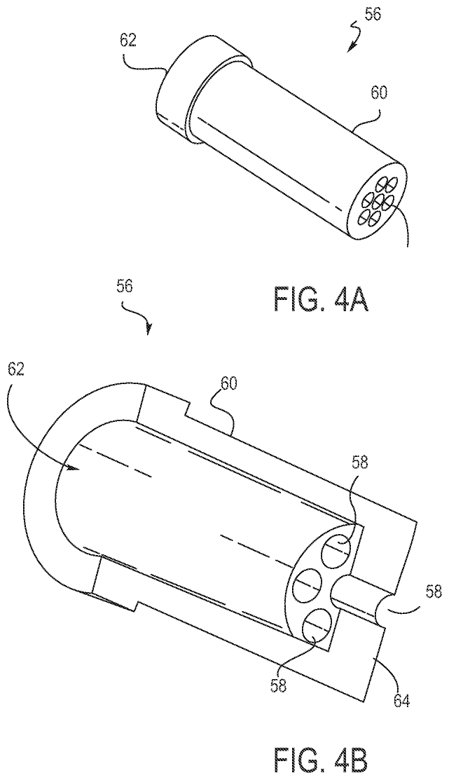

Referring to FIGS. 4A-4B, diagrams are shown of an exemplary insert 56. FIG. 4A shows a perspective view of the insert 56, while FIG. 4B shows a cross-section.

As illustrated in the two figures, the insert 56 includes a hollow cylinder 60 having a purge gas inlet end 62 and a purge gas outlet end 64. The holes 58 are provided at the gas purge outlet end.

The inserts 56 are configured to be selectively inserted into the holes 54 provided in the faceplate 42. When inserted, the purge gas inlet 62 is in fluid communication with the plenum 41 formed between the top purge plate 34 and the faceplate 42. The purge gas thus flows from the plenum 41, down the hollow cylinder 60, and out the holes 58, immediately above the device side of the substrate.

It should be noted that the particular embodiment of the faceplate 42, configurable gas outlets 44 and the inserts 56 as illustrated in FIGS. 3A-3B and 4A-4B is merely exemplary and should not be construed as limiting in any regard. On the contrary, the faceplate 42 may assume any desirable shape, although in general, it will assume the same or a similar shape as the substrate. Also, the number and arrangement of the configurable gas outlets 44 may also widely vary. The number of the configurable gas outlets 44 may be more or fewer than eighteen (18) and they may be arranged in any pattern on the faceplate 42. In addition, the inserts 56 can also be modified as needed or desired. For instance, the number of holes 58 at the purge gas outlet end 64 of the insert 56 may be varied to either increase or decrease the overall total number of holes, depending on need, flow rates, or other specifications.

In one specific, but not exclusive, embodiment, the diameter of the holes 56 is approximately 0.04 of an inch, or 1.0 millimeters. In other embodiments, the diameter of the holes can be larger or smaller, ranging for example from 0.001 to 0.06 inches. The size or diameter of the holes 56 may also vary as needed to meet purge gas flow rates or other specifications.

The frequency of the RF used in the processing chamber 12 may also impact the diameter of the holes 56 that may be used. For instance with an RF of 27.112 MHz, smaller diameter of the holes 56 are required than if 13.56 MHz is used. At the higher RF frequency, the smaller diameter is needed to prevent hollow-cathode discharging or arcing, which can damage devices on the substrate.

With the use of the inserts 56, the purge gas flow rates can be selectively adjusted or controlled in a number of ways. First, the number of configurable gas outlets 44 may be varied. Second, if a particular showerhead assembly 18 has more configurable gas outlets 44 that may be needed, then inserts 56 with no holes 58 may be inserted and used as “plugs”. Third, when inserts 56 with holes 58 are used, the number, pitch and diameter of the holes 58 can all be varied to meet a desired or needed flow rate. The use of the inserts 56 provides the advantage that the showerhead assembly 18 can be configured in the field, even after the deposition tool 10 has been installed at a customer location. By disassembling the showerhead assembly 18, for example during routine maintenance, the inserts 56 can be changed as needed to meet changing operating conditions. Similarly, if the RF used by a tool changes, then new inserts with the proper sized holes 58 can be easily substituted in the field for this reason as well.

In addition, the inserts 56 used for a given showerhead assembly do not all have to be the same. For instance, certain inserts 56 can have a different number of holes 58 or a different pattern of holes 58 than other inserts 56, or some inserts 56 can have holes 58 whereas other inserts 56 may not. As a result, the localized flow of the purge gas by each insert 56 can be highly configurable with respect to the device side of the substrate. Under certain circumstances for example, it may make sense to have a higher flow rate of the purge gas in the vicinity of the center of the substrate while having a lower flow rate at the periphery. In which case, the inserts 56 used toward the center of the faceplate 42 are configured to have a higher flow rate, while those toward the periphery have a lower flow rate. This is just one example of how the configurable gas outlets 44 of showerhead assembly 18 can be configured to control the localized flow of the purge gas above different regions of the device side of the substrate as needed or desired. By using inserts 56 having a different numbers of holes 58, arrangement or pattern of holes 58, diameter of the holes 58, and strategically placing the different inserts 56 at different locations of the faceplate 42, the localized purge gas flow patterns above the device side of the substrate can be controlled or tailored in an almost infinite number of ways.

In a non-exclusive embodiment, the showerhead assembly 18 is made of ceramic. The use of ceramic offers a number of benefits, including thermal and geometric stability, a high tolerance at elevated temperatures upwards of 600° C. or even higher, low particle generation, and resistance to process gasses such as nitrogen Tri-Fluoride (NF3) and/or other gases that may be used during a Remote Plasma Clean (RPC). Ceramic also offers the benefits of longevity and a reasonable manufacturing cost. While ceramic is a suitable material, others can be used as well, such as a ceramic coated metal.

The showerhead assembly 18 also responsible for heating the substrate during the backside deposition. In different embodiments, the showerhead assembly includes either a single zone heating element or multi-zone heating elements (both not illustrated), in addition to the other provided utilities as mentioned above. The showerhead assembly 18 typically heats the substrate in the range of 510° C. to 520° C.

The showerhead assembly 18 can also be used to deliver in-situ cleaning gasses during routine cleaning cycles of the processing chamber 18. Such cleaning gasses may include fluorine for example. In addition to cleaning the exposed surfaces within the processing chamber 12, the cleaning gasses will also clean exposed portions of the showerhead assembly 18, including the faceplate 42 and the individual holes 58 of the inserts 56.

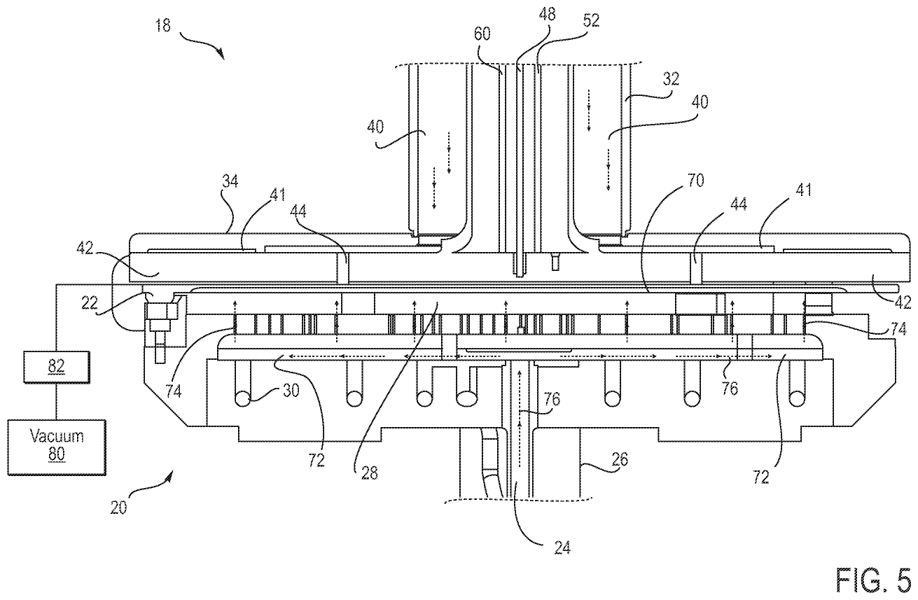

Referring to FIG. 5, a cross section view of the showerhead assembly 18 and the deposition pedestal 20 during backside deposition and device side purging is illustrated.

A substrate 70 is supported around its periphery by the substrate ring 22 of the deposition pedestal 20. With this arrangement, a substantial portion of the backside of the substrate is exposed within the underlying gap 28.

During backside deposition, a deposition gas flows up through the supply tube 24 within the stem 26, is heated by the heating elements 30, and then is laterally distributed within a plenum 72. Once distributed inside the plenum 72, the deposition gas flows upward into the gap 28 via an array of through holes 74 formed through the top surface of the deposition pedestal 20. The arrows 76 depict the path the deposition gas flows through the deposition pedestal 20 and into the gap 28. The back surface of the substrate 70 is therefore exposed to the deposition gas. When an RF is applied, a plasma is generated in the processing chamber 12 as well as the gap 28, and as a result, a thin film is formed on the backside of the substrate 70.

By controlling the temperature of the a deposition gas, both so called high or low backside depositions may be performed. As previously noted when the deposition is performed at the higher temperatures, the resulting layer better maintains its tensile and compressive strength during subsequent high temperature processing steps. As a result, the substrate remains substantially flat even when subject to elevated temperatures, such as those experienced during annealing or high temperature depositions.

In various embodiments, the deposition gas is typically silicon bearing, such as a gas containing Nitride, Carbon Dioxide, Carbon Monoxide, Silane or a combination thereof. In yet other embodiments, a vaporized precursor such as Tetraethyl Orthosilicate (TEOS) may be used as well.

During the backside deposition, the showerhead assembly 18 heats the substrate 70 in the range of 510° C. to 520° C. and supplies a continuous flow of the purge gas across the device surface of the substrate 70. The travel path of the purge gas includes supply inlet 38, the plenums 40 and 41 and through the holes 58 of the inserts 56 provided in the configurable gas outlets 44 of the faceplate 42. A vacuum 80, fluidly coupled via a valve 82 to the space above the substrate, applies a vacuum pressure to remove the purge gas above the substrate. Any backside deposition material that incidentally makes its way into the space above the device side of the substrate is swept away by the flow of the purge gas. As a result, incidental film deposition on the device surface of the substrate is mitigated or altogether eliminated.

It should be understood that the embodiments provided herein are merely exemplary and should not be construed as limiting in any regard. Although only a few embodiments have been described in detail, it should be appreciated that the present application may be implemented in many other forms without departing from the spirit or scope of the disclosure provided herein. Therefore, the present embodiments should be considered illustrative and not restrictive and is not to be limited to the details given herein, but may be modified within the scope and equivalents of the appended claims.

What is claimed is:

1. A deposition tool, comprising:
a processing chamber;
a deposition pedestal for supporting a substrate in the processing chamber and for depositing a film of material on a first surface of the substrate; and
a showerhead assembly having a faceplate opposing a second surface of the substrate, the faceplate of the showerhead having a plurality of configurable gas outlets arranged to distribute a purge gas adjacent the second surface of the substrate when the film of material is being deposited on the first surface of the substrate.

2. The deposition tool of claim 1, further comprising a plurality of inserts, each of the inserts arranged to be inserted in to a corresponding one of the configurable gas outlets respectively.

3. The deposition tool of claim 2, wherein each of the inserts are removable and can be replaced with another insert of a different configuration to reconfigure the corresponding configurable gas outlet.

4. The deposition tool of claim 2, wherein each of the inserts has one or more holes for distributing the purge gas adjacent the second surface of the substrate.

5. The deposition tool of claim 3, wherein the each of the one or more holes has a diameter ranging from 0.001 to 0.06 inches.

6. The deposition tool of claim 2, wherein two or more of the plurality of inserts are different and define different localized flow patterns of the purge gas with respect to the second surface of the substrate.

7. The deposition of claim 3, wherein a diameter of the one or more holes is dependent on a frequency of a Radio Frequency (RF) source applied to the process chamber, wherein the higher the frequency of the RF source the smaller the diameter, while the lower the frequency the larger the diameter.

8. The deposition tool of claim 2, wherein at least one of the inserts acts as a plug for stopping flow of the purge gas through the corresponding configurable gas outlet.

9. The deposition tool of claim 1, wherein the showerhead assembly is at least partially made of a material that is capable of withstand temperatures of approximately 400° C. or higher.

10. The deposition tool of claim 1, wherein the showerhead assembly is at least partially made of ceramic.

11. The deposition tool of claim 2, wherein the plurality of inserts are made of ceramic.

12. The deposition tool of claim 1, wherein the showerhead assembly further includes:
a cylinder;
a plenum, included in the cylinder, for supplying the purge gas to the faceplate of the showerhead assembly.

13. The deposition tool of claim 1, wherein the showerhead assembly further comprising an adaptor plug arranged to be at least partially inserted into the cylinder, the adaptor plug including a supply inlet for supplying the purge gas to the plenum included in the cylinder.

14. The deposition tool of claim 1, wherein the showerhead assembly further includes:
a cylinder;
an adaptor plug arranged to be inserted at least partially into the cylinder; and
one or more clamps for clamping the adaptor plug at least partially into the cylinder.

15. The deposition tool of claim 14, further comprising a compression ring provided between the adaptor plug and the cylinder.

16. The deposition tool of claim 1, wherein the showerhead assembly further includes:
a cylinder;
an adaptor plug arranged to be inserted at least partially into the cylinder, the adaptor plug configured to accommodate one or more of the following:
(a) an RF power supply rod;
(b) a power supply conduit; or
(c) a Thermo Couple.

17. The deposition tool of claim 1, wherein the purge gas is an inert gas.

18. The deposition tool of claim 1, wherein the purge gas is selected from one of the following:
(a) Nitrogen;
(b) Argon;
(c) Helium; or
(d) any combination of (a) though (c).

19. The deposition tool of claim 1, further comprising a vacuum and a valve for removing the purge gas from a space adjacent the second surface of the substrate.

20. The deposition tool of claim 1, wherein the showerhead assembly further includes a plenum provided adjacent the faceplate for supplying the purge gas to the configurable gas outlets.

21. An insert arranged to be inserted into a configurable gas outlet of a showerhead of a deposition tool, the insert configured to, when inserted into the configurable gas outlet, configure the flow of a purge gas out of the configurable gas outlet and adjacent a first surface of a substrate, the flow of the purge gas preventing or mitigating deposition of a material on the first surface while the material is being deposited on a second surface of the substrate.

22. The insert of claim 21, wherein the insert is removable from the configurable gas outlet and can be selectively replaced with another insert with different flow characteristics of the purge gas.

23. The insert of claim 21, wherein the insert is a hollow cylinder including an inlet for receiving the purge gas and an outlet for dispensing the purge gas,
wherein, when the insert is inserted into the configurable gas outlet, the inlet is arranged to receive the purge gas from a supply plenum provided within the showerhead and the outlet is arranged to dispense the purge gas adjacent the first surface of a substrate.

24. The insert of claim 21, wherein the insert includes an outlet for dispensing the purge gas adjacent the first surface of the substrate, the outlet including one or more holes for dispensing the purge gas.

25. The insert of claim 24, wherein the each of the one or more holes has a diameter ranging from 0.001 to 0.06 inches.

26. The insert of claim 24, wherein a diameter of the one or more holes is dependent on a frequency of a Radio Frequency (RF) source used by the deposition tool.

27. The insert of claim 21, wherein the inserts acts as a plug for plugging the flow of the purge gas through the configurable gas outlet.
